(19) United States
(12) Patent Application Publication
(10) Pub. No.: US 2006/0261823 A1
(43) Pub. Date: Nov. 23, 2006

(54) Apparatus for measuring voltage of a voltage source

(76) Inventor: Robert Parker, Bend, OR (US)

Correspondence Address: Squire, Sanders & Dempsey L.L.P.;Two Renaissance Squire, Suite 2700, 40 North Central Avenue, Phoenix, AZ, 85004-4498, US

(21) Appl. No.: 11/135,730

(22) Filed: May 23, 2005

(51) Int. Cl. G01R 27/08

(52) U.S. Cl. 324/713

(57) ABSTRACT

An apparatus is delineated for measuring voltage of a voltage source. An embodiment of the apparatus may comprise a substrate; a plurality of temperature responsive displays printed on the substrate; a plurality of heat generating elements printed on the substrate, each heat generating element being thermally coupled to at least one of the temperature responsive displays; a reference voltage circuit coupled to the substrate and operative to produce a reference voltage; a voltage divider network coupled to the substrate and including a plurality of surface mounted resistors electrically connected in series and operative to produce a plurality of voltages; and a plurality of comparator circuits embodied in a surface mounted device, each comparator circuit operative to receive the reference voltage and a respective voltage of the plurality of voltages produced by the voltage divider network, and selectively allow current to flow through at least one of the heat generating elements when the respective voltage supplied by the voltage divider network exceeds the reference voltage.

### FIELD OF THE INVENTION

The present invention relates to apparatus for measuring voltage of a voltage source, and more particularly, to a battery tester for a battery-powered device.

### BACKGROUND OF THE INVENTION

Systems employing thermochromic materials for testing the relative charge on a voltage source, e.g., a battery, are well known. An example of one such system is that commonly found in a package of DURACELL batteries. This system uses a tapered resistance conductor printed on one side of a thin polyester film with a thermochromic material printed on the other side of the film. When a voltage is applied across the tapered resistance conductor, a portion of the conductor roughly proportional to the state of charge of the battery is heated sufficiently to cause a corresponding portion of the thermochromic material to change from opaque to transparent, thus providing an indication of the relative voltage or state of charge of the battery. These systems work well for batteries, such as alkaline batteries, in which the relative voltage varies significantly from a fully charged condition to a depleted condition, for example, 50 percent or from 1.55 volts to 1.0 volts.

However, such tapered resistance systems do not work as well for some other types of batteries where the voltage delivered by a depleted battery is not a significant percent lower than the voltage delivered by a fully charged battery. For example, a lead-acid battery which is typically used in a car, truck or boat exhibits a very small change in voltage with respect to a large decrease in the charge of the battery. For instance, a lead-acid car battery may be at 12.8 volts when fully charged and decrease only to 12 volts when the battery is completely discharged. Rechargeable nickel-cadmium batteries, such as are used in portable computers, video cameras, power tools and the like, also exhibit a relatively small change in voltage with respect to a large change in battery charge. In the case of nickel-cadmium batteries, it is also desirable to be able to measure the voltage of the battery accurately in order to ascertain when the battery needs to be recharged. Nickel-cadmium batteries have a memory effect and thus should be almost completely discharged before recharging to promote a complete charge and longer battery life. However, these batteries should not be discharged completely or voltage reversal of the battery can result.

U.S. Pat. No. 5,610,511 (“'511 patent”), which is entitled “Temperature Responsive Battery Tester,” filed by the present inventor, Robert Parker, and incorporated herein by reference, discloses a battery tester that is capable of accurately measuring small changes in the voltage delivered by a battery. A schematic of the battery tester is shown in FIG. 31 of the '511 patent and FIG. 1 herein.

Referring to FIG. 1, a voltage tester 10 is shown employing a zener diode 12 in combination with a series of comparators 14A-14H in a voltage divider network 16 to produce a bar graph display. Herein multiple like components, e.g., comparators 14A-14H, will be referred to generally by a reference number alone, e.g., comparator 14, and only when it is desired to distinguish between like items in the tester will the alphabetical character also be used, e.g., comparator 14A.

When voltage tester 10 is connected to battery 18 to be tested, battery 18 is electrically connected across zener diode 12 in series with a current limiting resistor 20. Zener diode 12 functions as a voltage regulator at breakdown essentially fixing the voltage over line 22 connecting zener diode 12 and current limiting resistor 20 when zener diode 12 is in its breakdown state. Hence, the voltage applied to line 22 and to the noninverting terminal 24 of each comparator 14 is fixed at a selected voltage, e.g., 5.5 volts, which serves as the reference voltage for comparators 14.

In operation, comparators 14 each act as a switch selectively allowing current from battery 18 to be applied through line 26 and a selected resistor 28A-28H corresponding to a selected comparator 14A-14H. Each resistor 28 is thermally coupled to a temperature responsive display (not shown) which changes states, such as from black to a certain color, when a current is applied through the corresponding resistor 28A-28H. The temperature responsive displays may be any of a variety of shapes arranged in a variety of ways to provide a discernible output, for example, a bar graph.

When the voltage at noninverting terminal 24 of comparator 14 exceeds the voltage at inverting terminal 30, current is not permitted to flow through resistor 28 and the corresponding display will not change states, i.e., will remain black. If the reverse is true, i.e., the voltage at inverting terminal 30 of comparator 14 exceeds the voltage at noninverting terminal 24, then comparator output 32 is coupled to ground allowing current to flow from battery 18 through line 26 and through the corresponding resistor 28 to ground. Resistor 28 will thus heat causing the temperature responsive display coupled to that resistor to change states, for example, from black to red. Since the reference voltage provided to noninverting input 24 is a function of the breakdown or threshold conducting voltage of zener diode 12, the testing range of voltage tester 10 may be shifted by selecting a zener diode with a different breakdown voltage.

The voltage applied to the inverting terminals 30 of the individual comparators 14 is determined by voltage divider network 16 connected in parallel with battery 18. Voltage divider network 16 includes a number of voltage dividing resistors 34 connected in series with one another, with each of the lines 36 connecting individual resistors 34 being connected to inverting terminals 30 of comparators 14. As a result each comparator 14 is exposed to a different voltage at its inverting terminal 30 which is a function of the number of voltage dividing resistors 34, and thus the total resistance, between the connection of the inverting terminal 30 to line 36 and battery 18. For example, the voltage applied to inverting terminal 30A of comparator 14A will be greater than the voltage applied to inverting terminal 30B of comparator 14B, which will be greater than the voltage applied to inverting terminal 30C of comparator 14C, and so on.

Therefore, with the proper values of the resistors 34 in voltage divider network 16, during operation comparator 14A will have its output 32A connected to ground when battery 18 has a voltage equal to or greater than a voltage which is at the bottom of the testing range, and comparator 14H will have its output 32H connected to ground when battery 18 has a voltage at the top of the testing range. Intermediate comparators 14B-G will have their respective outputs 32B-32G connected to ground at incremental voltages along the voltage testing range. Voltage tester 10 is thus able to provide a visual indication of battery voltage at a number of voltage levels.

As an example, consider voltage tester 10 having a testing range of 12.3 volts to 13.0 volts and a bar graph display including eight visual bands indicating battery voltages evenly divided between 12.3 volts and 13.0 volts. Over the expected range of battery voltages zener diode 12 would act to provide a reference voltage of 5.5 volts to noninverting inputs 24A-24H of the comparators 14A-14H. Voltage dividing resistors 34 of voltage divider network 16 would have resistance values chosen so that when voltage source 18 delivers 13.0 volts, the voltage at inverting input 30H of comparator 14H would be 5.5 volts and the voltage at each of inverting inputs 30A-30G would be greater than 5.5 volts; when voltage source 18 delivers a voltage of 12.9 volts, the voltage at inverting input 30H would be less than 5.5 volts while the voltage at inverting input 30G would be 5.5 volts and the voltages at inverting inputs 30A-30F would be greater than 5.5 volts; and so on until voltage source 18 delivers only 12.3 volts, at which time only the voltage at inverting input 30A of comparator 14A is at 5.5 volts and the voltages at inverting inputs 30B-30H are less than 5.5 volts.

If such a voltage tester 10 is connected to a fully charged battery 18 delivering 13.0 volts, the voltages at all of inverting inputs 30A-30H will be at 5.5 volts or greater and all of comparators 14A-14H will essentially switch “on” to couple their respective outputs 32A-32H to ground so that current flows from battery 18 through resistors 28A-28H and causes each of the corresponding temperature responsive displays to change states from black to a discernible color. Conversely, if battery 18 to which voltage tester 10 is connected is less than fully charged and delivers only 12.9 volts, only comparators 14A-14G will switch “on” and only the temperature responsive displays corresponding to resistors 28A-28G will change states, thus visually indicating a lower battery voltage. Further, if battery 18 is more fully discharged so that it delivers only 12.3 volts, only comparator 14A will switch “on” and only the temperature responsive display corresponding to resistor 28A will change states thus indicating a low battery voltage.

As disclosed by the '511 patent, resistors 20, 28 and 34, and lines 22, 36 and 26 are printed on a surface of a substrate with zener diode 12 and comparators 14 being surface mounted devices mounted to the appropriate passive elements on the surface of the substrate. The '511 patent states that an advantage of voltage tester 10 is that its accuracy is dependent mainly upon the ratio of the various resistors 34 in voltage divider network 16, as opposed to their actual values. According to the '511 patent, the ratio of resistors 34 in voltage divider network 16 is governed by the graphic accuracy of the printing process.

The '511 patent did not realize or disclose several disadvantages resulting from the use of printed resistors 34 for voltage divider network 16. For example, in order for voltage tester 10 to have a reasonably accurate voltage divider network 16, printed resistors 34 have to be quite large, e.g., each having a length in the range of 0.4 to 1.2 inches and a width in the range of 0.1 to 0.25 inches, necessitating a relatively large voltage tester 10, e.g., having in one case a length of approximately 11 inches and a width of approximately 1 inch and having in another case a length of approximately 4 inches and a width of approximately 3 inches, in either case the tester area including approximately 11 to 12 square inches. This tends to restrict use of voltage tester 10, i.e., it may be undesirable or impractical to use voltage tester 10 to test a voltage source on a device of a certain size, e.g., smaller than voltage tester 10 with respect to one or more dimensions. Additionally, because the use of printed resistors 34 necessitates a relatively large voltage tester 10, the number of voltage testers 10 that can be made for a given area or sheet of material, e.g., substrate material, is unduly limited. Moreover, the cost to print resistors 34 increases as the total area required for resistors 34 increases, raising the manufacturing cost of voltage tester 10. Another problem resulting from the use of printed resistors 34 for voltage divider network 16 is the tolerance of printed resistors 34, which is typically quite high, e.g., approximately ±10 percent of rated resistance, tending to limit the accuracy of voltage tester 10.

Thus, there is a need for voltage testers that overcome these and other problems of the prior art.

### SUMMARY OF THE INVENTION

In accordance with an embodiment of the invention, an apparatus is disclosed for measuring voltage of a voltage source, the apparatus comprising a substrate; a plurality of temperature responsive displays printed on the substrate; a plurality of heat generating elements printed on the substrate, each heat generating element being thermally coupled to at least one of the temperature responsive displays; a reference voltage circuit coupled to the substrate and operative to produce a reference voltage; a voltage divider network coupled to the substrate and including a plurality of surface mounted resistors electrically connected in series and operative to produce a plurality of voltages; and a plurality of comparator circuits embodied in a surface mounted device, each comparator circuit operative to receive the reference voltage and a respective voltage of the plurality of voltages produced by the voltage divider network, and selectively allow current to flow through at least one of the heat generating elements when the respective voltage supplied by the voltage divider network exceeds the reference voltage.

In accordance with another embodiment of the invention, an apparatus is disclosed for measuring voltage of a voltage source, the apparatus comprising a substrate; a plurality of temperature responsive displays coupled to the substrate; a plurality of heat generating elements coupled to the substrate, each heat generating element including a positive temperature coefficient ink and being thermally coupled to at least one of the temperature responsive displays; a reference voltage circuit coupled to the substrate and operative to produce a reference voltage; a voltage divider network coupled to the substrate and operative to produce a plurality of voltages; and a plurality of comparator circuits coupled to the substrate, each comparator circuit operative to receive the reference voltage and a respective voltage of the plurality of voltages produced by the voltage divider network, and selectively allow current to flow through at least one of the heat generating elements when the respective voltage supplied by the voltage divider network exceeds the reference voltage.

In accordance with yet another embodiment of the invention, an apparatus is disclosed for measuring voltage of a voltage source, the apparatus comprising a substrate; a plurality of temperature responsive displays coupled to the substrate; a plurality of heat generating elements coupled to the substrate, each heat generating element being thermally coupled to at least one of the temperature responsive displays; a reference voltage circuit coupled to the substrate and operative to produce a reference voltage; a voltage divider network coupled to the substrate and operative to produce a plurality of voltages; a switch operative to selectively complete a circuit to permit measuring the voltage of the voltage source; and a plurality of comparator circuits coupled to the substrate, each comparator circuit operative to receive the reference voltage and a respective voltage of the plurality of voltages produced by the voltage divider network, and selectively allow current to flow through at least one of the heat generating elements when the respective voltage supplied by the voltage divider network exceeds the reference voltage.

Additional objects and advantages of the invention will be set forth in part in the description which follows, and in part will be obvious from the description, or may be learned by practice of the invention. The objects and advantages of the invention will be realized and attained by means of the elements and combinations particularly pointed out in the appended claims.

It is to be understood that both the foregoing general description and the following detailed description are exemplary and explanatory only and are not restrictive of the invention, as claimed.

The accompanying drawings, which are incorporated in and constitute a part of this specification, illustrate several embodiments of the invention and together with the description, serve to explain the principles of the invention.

### BRIEF DESCRIPTION OF THE DRAWINGS

FIG. 1 is an electrical schematic of a prior art battery tester.

FIG. 2 is an electrical schematic of an embodiment of an apparatus for measuring voltage of a voltage source, in accordance with the present invention.

FIG. 3 is a plot of resistance magnification versus temperature for a heat generating element employing a positive temperature coefficient ink, in accordance with the present invention.

FIG. 4 is a plan view of an embodiment of an apparatus for measuring voltage of a voltage source, in accordance with the present invention.

FIG. 4A is a cross-sectional view taken along the line 4A-4A of FIG. 4 showing a switch in an open condition, in accordance with the present invention.

FIG. 4B is a cross-sectional view of the switch of FIG. 4A shown in a closed condition, in accordance with the present invention.

FIG. 5 is a plan view of the apparatus of FIG. 4, shown in an open condition to illustrate an exemplary circuit layout, in accordance with the present invention.

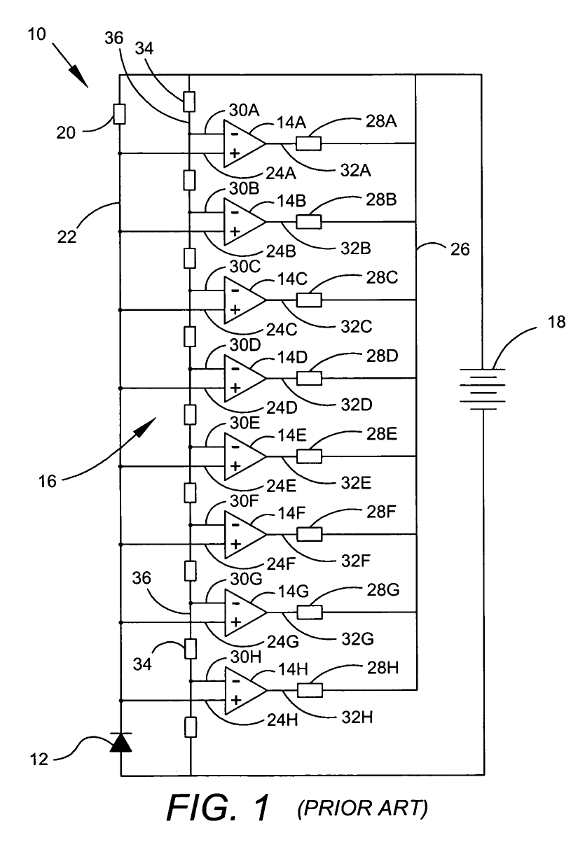

### DESCRIPTION OF THE EMBODIMENTS

Reference will now be made in detail to the present exemplary embodiments of the invention, examples of which are illustrated in the accompanying drawings. Wherever possible, the same reference numbers will be used throughout the drawings to refer to the same or like parts.

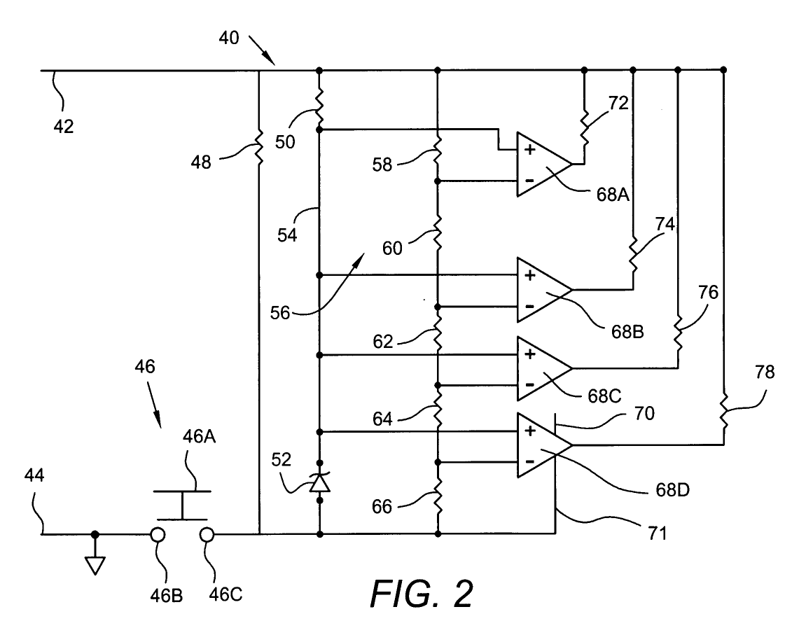

Referring to FIG. 2, an electrical schematic is shown of an embodiment of an apparatus for measuring voltage of a voltage source (hereafter “voltage tester 40”). Voltage tester 40 may be employed to provide indications of voltage of a voltage source, such as a battery. To provide such indications, voltage tester 40 may include a switch 46, resistors 48 and 50, a reference voltage circuit 52, a voltage divider network 56, a plurality of comparator circuits 68A-68D, a plurality of heat generating elements 72-78 and a plurality of temperature responsive displays, which are not shown but may be thermally coupled to the plurality of heat generating elements 72-78.

A voltage source, such as a battery, may be coupled by any suitable means across terminals 42 and 44. In one embodiment, terminals 42 and 44 may be physically connected, respectively, to a positive and a negative terminal of the battery, which may comprise a power source for a device (not shown). In this manner, voltage tester 40 may be permanently connected to the battery, eliminating the past need for a user to hold terminals of a battery tester to the battery terminals to take a reading.

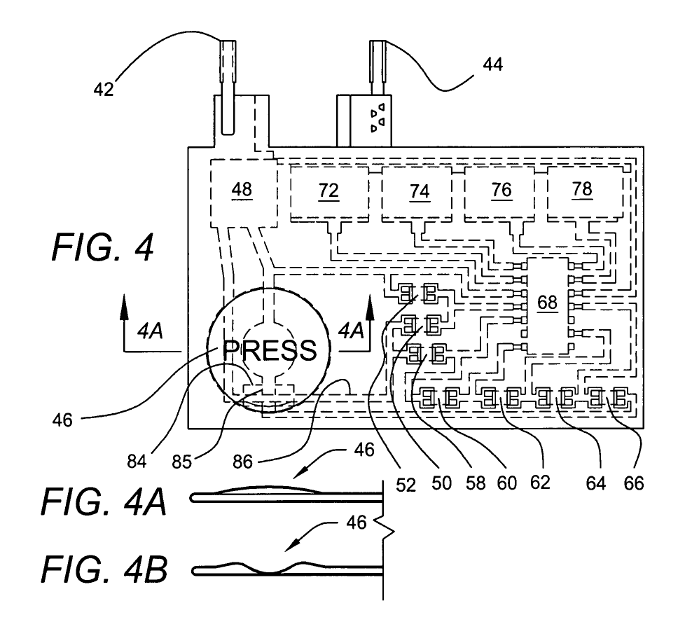

Switch 46 may comprise any structure suitable to selectively complete a circuit between the battery and voltage tester 40. In one embodiment, switch 46 may include an actuator 46A and contact regions 46B and 46C, which may comprise two printed conductive regions, such as printed silver ink. As is evident from FIGS. 4A and 4B, actuator 46, as shown schematically in FIG. 2, may comprise anything, e.g., a user's finger or any selectively-driven mechanical structure, which may be employed to selectively press contact regions 46B and 46C together to make contact. Contact region 46B may be coupled to terminal 44, while contact region 46C may be coupled to a terminal of resistor 48.

In a first state, as shown in FIG. 4A, contact regions 46B and 46C do not make contact with each other, forming an open circuit between the battery and voltage tester 40. Thus, in this first state, voltage tester 40 does not provide indications of voltage of the battery. In a second state, as shown in FIG. 4B, actuator 46A presses contact regions 46B and 46C together to make contact with each other, completing a circuit between the battery and voltage tester 40. Thus, in this second state, voltage tester 40 may provide indications of voltage of the battery. In one embodiment, a supporting structure, e.g., substrate material, for either of contact regions 46B or 46C may be mechanically biased, such as by embossing the relevant supporting structure, to make the first state the default state for switch 46. In this manner, switch 46 may be normally open, and closed when actuator 46 is employed to press contact regions 46B and 46C together to make contact.

Resistor 48 may comprise any structure suitable for placing a heavy load on the battery, i.e., a low resistance for temporarily drawing relatively high battery current when switch 46 is initially closed. This may serve to improve the accuracy of voltage readings by voltage tester 40. One terminal of resistor 48 may be coupled to terminal 42, while the other terminal of resistor 48 may be coupled to contact region 46C.

In one embodiment, resistor 48 may comprise a printed resistor, such as a resistor printed using carbon ink providing a predefined resistance per square, e.g., approximately 100 to 500 ohms per square, and having a suitably low resistance value to temporarily draw relatively high battery current when switch 46 is initially closed, e.g., a 500 to 1000 ohm resistor to draw approximately 12 to 24 milliamps for a 12 volt battery. In a variation to this embodiment, a thermochromic material, such as a thermochromic ink with any desired transition temperature, may be placed, such as by a printing process, in thermal contact with resistor 48 for purposes of indicating when the battery is fully drained. Matsui International Company and Liquid Crystal Resources each have a variety of suitable thermochromic inks available with transition temperatures ranging upward from approximately 45 degrees Celsius.

For example, a fully drained condition for a 12 volt battery may be when the battery may supply less than 10 milliamps. In such a condition, when switch 46 is closed, insufficient current is drawn from the battery through resistor 48 to heat the thermochromic material above its transition temperature, e.g., approximately 45 to 60 degrees Celsius. As such, a suitable indicator, such as an indicator reading “TEST,” located beneath the thermochromic material would not be visible to a user, indicating to the user that the battery is fully drained. Conversely, when the battery is not fully drained and switch 46 is closed, sufficient current is drawn from the battery through resistor 48 to heat the thermochromic material above its transition temperature. In this case, a suitable indicator, such as an indicator reading “TEST,” located beneath the thermochromic material would be visible to a user, indicating to the user that the battery is not fully drained and testing of the battery voltage is in progress.

Reference voltage circuit 52 may comprise any structure suitable for providing a desired reference voltage, e.g., 8.2 volts, for voltage tester 40 when employed to measure battery voltage of a predefined level, e.g., 12 volts. In one embodiment, reference voltage circuit 52 may comprise a surface-mounted zener diode, such as a zener diode sold under part no. BZT52C8V2 from Fairchild Semiconductor, which is rated to provide approximately 8.2 volts at breakdown and dissipate up to ½ watt. Resistor 50 may comprise any resistor suitable to limit current through reference voltage circuit 52 to a desired level, e.g., one that prevents damaging reference voltage circuit 52. In one embodiment, resistor 50 may comprise a 20 Kohm surface-mounted resistor. Resistor 50 may be coupled at one terminal to terminal 42, while the other terminal of resistor 50 may be coupled to a terminal of reference voltage circuit 52; the other terminal of reference voltage circuit 52 may be coupled to contact region 46C.

Voltage divider network 56 may comprise any suitable plurality of surface mounted resistors providing desired voltages to a respective plurality of comparator circuits 68A-68D. In one embodiment, voltage divider network may include surface mounted resistors 58-66. Resistor 58 may be coupled at one terminal to terminal 42 and coupled at its other terminal to a terminal of resistor 60. The other terminal of resistor 60 may be coupled to a terminal of resistor 62, while the other terminal of resistor 62 may be coupled to a terminal of resistor 64. The other terminal of resistor 64 may be coupled to a terminal of resistor 66, while the other terminal of resistor 66 may be coupled to contact region 46C. When voltage tester 40 is employed to provide battery voltage indications for a 12 volt battery, surface mounted resistors 58-66 may provide respective resistances of 49.9 Kohms, 2.43 Kohms, 2.43 Kohms, 1.69 Kohms and 100 Kohms. Such surface mounted resistors 58-66 with a tolerance of approximately 1 percent of rated resistance may be provided by ROHM Co., Ltd., Yageo Corporation, SUSUMU Co., Ltd., Panasonic Corporation and other such companies.

The plurality of comparator circuits may comprise any suitable plurality of comparator circuits for selectively providing current to a respective plurality of heat generating elements. In one embodiment, the plurality of comparator circuits may comprise comparators 68A-68D which may be provided by a surface mounted package sold under part no. LM339 from Texas Instruments Incorporated. The noninverting input of comparator 68A may be coupled to a conductor between resistor 50 and reference voltage circuit 52, while the inverting input of comparator 68A may be coupled to a conductor between resistors 58 and 60. The noninverting input of comparator 68B may be coupled to a conductor between resistor 50 and reference voltage circuit 52, while the inverting input of comparator 68B may be coupled to a conductor between resistors 60 and 62. The noninverting input of comparator 68C may be coupled to a conductor between resistor 50 and reference voltage circuit 52, while the inverting input of comparator 68C may be coupled to a conductor between resistors 62 and 64. The noninverting input of comparator 68D may be coupled to a conductor between resistor 50 and reference voltage circuit 52, while the inverting input of comparator 68D may be coupled to a conductor between resistors 64 and 66. Power and ground for comparators 68A-68D may be provided by coupling the positive terminal of the battery, e.g., at terminal 42, to a terminal 70 on comparator 68D and coupling the negative terminal of the battery, e.g., at terminal 44 (through switch 46) to a terminal 71 on comparator 68D.

The plurality of heat generating elements may comprise any suitable plurality of heat generating elements for heating a respective plurality of temperature responsive displays (not shown) thermally coupled to the plurality of heat generating elements. In one embodiment, the plurality of heat generating elements may comprise printed resistors 72-78, such as resistors printed using a positive temperature coefficient (“PTC”) carbon ink available from DuPont Corporation. When voltage tester 40 is employed to provide battery voltage indications for a 12 volt battery, resistors 72-78 may each provide resistances of approximately 500 ohms. Each of resistors 72-78 may be coupled at one terminal to the output of a respective one of the comparators 68A-68D, while the other terminals of resistors 72-78 may be coupled to terminal 42.

The plurality of temperature responsive displays (not shown but may be thermally coupled to the plurality of heat generating elements 72-78) may comprise any suitable plurality of temperature responsive displays for providing indications of battery voltage by changing their appearance in response to heat provided, in part, by a respective heat generating element 72-78 (ambient temperature may also affect the temperature responsive displays). In one embodiment, the temperature responsive displays may comprise a thermochromic material, such as a thermochromic ink with any desired transition temperature, which may be provided by any suitable means, e.g., a printing process, to thermally contact respective heat generating elements 72-78. Matsui International Company and Liquid Crystal Resources each have a variety of suitable thermochromic inks available with transition temperatures ranging upward from approximately 45 degrees Celsius.

In a preferred embodiment, the transition temperature of the thermochromic material is in the range of above 45 degrees Celsius to 60 degrees Celsius, and in a most preferred embodiment, 55 degrees Celsius to 60 degrees Celsius. It has been found that using thermochromic materials with transition temperatures in these ranges optimizes display performance by permitting use of voltage tester 40 in a wide range of ambient temperatures, e.g., from approximately 0 to 40 degrees Celsius.

When voltage tester 40 is connected to a battery to be tested and switch 46 is closed, the battery may be electrically connected across reference voltage circuit 52 in series with resistor 50. Reference voltage circuit 52, e.g., a zener diode, may function as a voltage regulator at breakdown essentially fixing the voltage over the line connecting reference voltage circuit 52 and resistor 50 when reference voltage circuit 52 is in its breakdown state. Hence, the voltage applied to the noninverting terminals of each comparator 68 is fixed at a selected voltage, e.g., 8.2 volts, which serves as the reference voltage for comparators 68.

When voltage tester 40 is connected to a battery to be tested and switch 46 is closed, the battery is also electrically connected across resistor 48 to place a heavy load on the battery, e.g., a low resistance for temporarily drawing relatively high battery current when switch 46 is initially closed. This may serve to improve the accuracy of voltage readings by voltage tester 40. Additionally, current drawn through resistor 48 may provide a “TEST” indication, as described above, to indicate to the user that the battery is not fully drained, the absence of such indication informing the user that the battery is fully drained.

In operation, comparators 68A-68D each may act as a switch to selectively allow current from the battery to be applied to a respective resistor 72-78 corresponding to a selected comparator 68A-68D. Each resistor 72-78 is thermally coupled to a temperature responsive display (not shown) which may changes states, such as from black to a certain color, when a current is applied through the corresponding resistor 72-78. The temperature responsive displays may be any of a variety of shapes arranged in a variety of ways to provide a discernible output, such as a bar graph.

When the voltage at the noninverting terminal(s) of one or more of the comparators 68A-68D exceeds the voltage at the corresponding inverting terminal(s), current is not permitted to flow through the corresponding resistor(s) 72-78 and the corresponding display(s) will not change states, i.e., will remain black. If the reverse is true, i.e., the voltage at the inverting terminal(s) of one or more of the comparators 68A-68D exceeds the voltage at the corresponding noninverting terminal(s), then the output(s) of the corresponding comparators(s) 68A-68D will be coupled to ground, allowing current to flow from the battery through the corresponding resistor(s) 72-78 to ground. One or more of the resistors 72-78 corresponding to selected comparators 68A-68D, i.e., those comparators 68A-68D with their output coupled to ground, will thus heat causing the corresponding temperature responsive displays coupled to those resistors 72-78 to change states, for example, from black to red when a transition temperature is traversed. Since the reference voltage that may be provided to the noninverting inputs of comparators 68A-68D may be a function of the breakdown or threshold conducting voltage of reference voltage circuit 52, e.g., a zener diode, the testing range of voltage tester 40 may be shifted by selecting reference voltage circuit 52, e.g., a zener diode, with a desired breakdown voltage.

The voltage applied to the inverting terminals of comparators 68A-68D may be determined by voltage divider network 56 that may be connected in parallel with the battery. Voltage divider network 56 may include a number of voltage dividing resistors 58-66 that may be connected in series with one another, with each of the lines connecting the individual resistors 58-66 being connected to the inverting terminals of comparators 68A-68D. As a result each comparator of comparators 68A-68D may be provided a different voltage at its inverting terminal which may be a function of the number of voltage dividing resistors 58-66, and thus the total resistance, between the connection of the respective inverting terminal and the battery. For example, the voltage applied to the inverting terminal of comparator 68A will be greater than the voltage applied to the inverting terminal of comparator 68B, which will be greater than the voltage applied to the inverting terminal of comparator 68C, and so on.

Therefore, with the proper values of resistors 58-66 in voltage divider network 56, during operation comparator 68A may have its output connected to ground when the battery has a voltage equal to or greater than a voltage which is at the bottom of the testing range, and comparator 68D may have its output connected to ground when the battery has a voltage at the top of the testing range. Intermediate comparators 68B and 68C may have their respective outputs connected to ground at incremental voltages along the voltage testing range. Voltage tester 40 may thus provide a visual indication of battery voltage at a number of voltage levels.

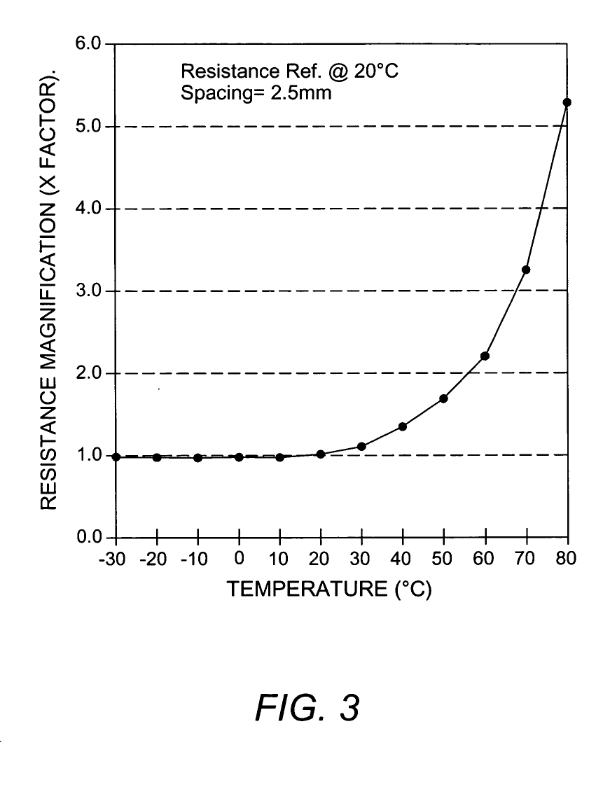

Referring to FIG. 3, a plot is shown of resistance magnification versus temperature for a PTC ink that may be used to form a heat generating element, such as heat generating elements 48 and/or 72-78, as shown in FIG. 2. When a heat generating element passes current, it may generate heat according to the square of its passing current (I) times the resistance of the heat generating element (R), i.e., I²R heat generation. Thus, when current (I) passes through a heat generating element with resistance (R), the element heats up according to I²R. When a PTC ink is used to form a heat generating element, such heating raises the temperature and resistance of the heat generating element, according to the PTC characteristics of the element.

Consider, for example, heat generating elements formed by printed PTC ink having the resistance magnification versus temperature transfer function shown in FIG. 3, which has a resistance reference temperature of 20 degrees Celsius and assumes spacing between adjacent heat generating elements of approximately 2.5 millimeters. This transfer function yields a resistance magnification factor of 1 when the temperature of a heat generating element is within the range of −30 degrees Celsius to 20 degrees Celsius. Thus, the resistance of heat generating elements at temperatures in this range does not appreciably increase. The transfer function of FIG. 3 yields a resistance magnification factor greater than one when the temperature of a heat generating element is above 20 degrees Celsius. Thus, the resistance of heat generating elements at temperatures above 20 degrees Celsius may appreciably increase. For example, if a heat generating element comprised a 1 Kohm resistor formed by printed PTC ink having the resistance magnification versus temperature transfer function shown in FIG. 3, when this resistor is at a temperature of approximately 40 degrees Celsius, the resistance magnification factor is approximately 1.3. This factor increases the resistance of the element to approximately to 1.3 Kohms, i.e., 1 Kohms×1.3.

Increasing the resistance of a heat generating element tends to reduce current flowing through the element. Reducing current flowing through a heat generating element tends to limit heating of the element. This is due to the squaring of the current factor in the I²R heat-generation computation. More specifically, although the resistance of a heat generating element may increase, the current passing through the element is reduced, due to the increased resistance. Since the current factor in the I²R computation is squared and the resistance factor is not squared, the reduction in the current factor generally has a more dominant effect on the heat-generation computation and the net result is more stabilized, controlled heating of the heat generating element.

Thus, using PTC ink to form a heat generating element may provide a negative feedback effect on temperature of the heat generating element, providing more stabilized, controlled heating of the element. Additionally, using PTC ink to form a heat generating element permits relatively rapid heating up to a predefined temperature, e.g., 20 degrees Celsius, followed by more stabilized, controlled heating of the heat generating element above the predefined temperature. As such, when a heat generating element, e.g., elements 48 and/or 72-78, is coupled to a temperature responsive display, the display may rapidly reach a transition temperature and change the appearance of the display, yet the use of PTC ink to form the heat generating element still tends to limit the heating of the element and surrounding materials.

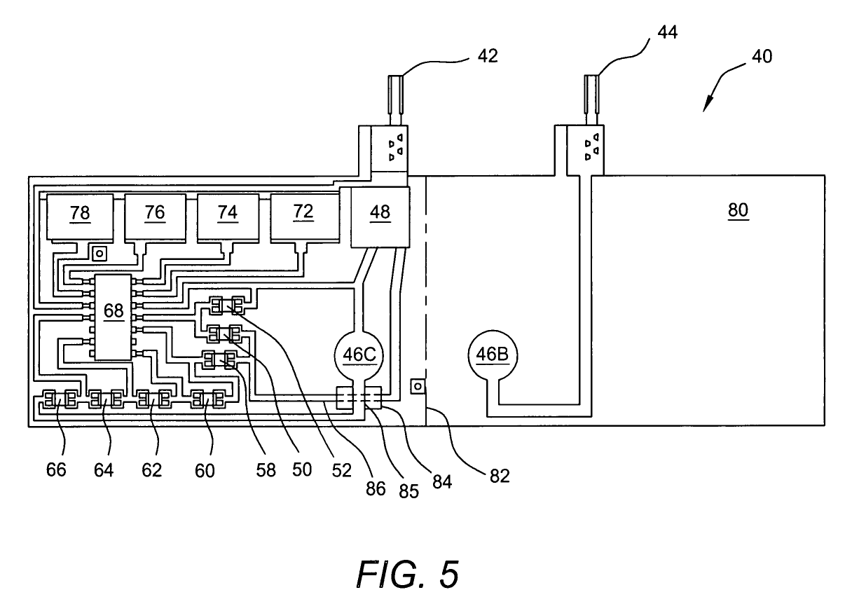

FIG. 5 is a plan view of voltage tester 40, shown in an open condition to illustrate an exemplary circuit layout, which may be made using any suitable techniques or materials.

For example, voltage tester may include a substrate 80, which may comprise any suitable material. In one embodiment, substrate 80 may comprise a generally lightweight and flexible material, such as a film of polyester, polycarbonate, any similar material or a combination of any of the foregoing. Typically, a sheet of substrate material may be processed to provide substrates 80 for several voltage testers 40. Assuming a sheet of substrate material 80 is employed, this material may be generally clear. It may be desirable to apply a darkening material on substrate 80 to improve the visibility of the displays for voltage tester 40. Thus, using any suitable technique, a layer of darkening material, such as a dark, e.g., black, ink, may be applied to one side of substrate 80, leaving open areas where the displays will go. Using any suitable technique, a layer of thermochromic material, such as a thermochromic ink having any desired transition temperature, may be applied in the display areas, e.g., regions corresponding to elements 48 and 72-78. Using any suitable technique, a layer of indicator material, such as an ink providing a prominently visible color, e.g., yellow, green, red, may be applied in the display areas, e.g., regions corresponding to elements 48 and 72-78. The indicator material may be laid out in any desired shape, including text to form one or more words, e.g., TEST for element 48. Using any suitable technique, a layer of indicator enhancing material, such as white ink, may be applied in the display areas, e.g., regions corresponding to elements 48 and 72-78. Indicator enhancing material of lighter color, e.g., white may enhance visibility of the displays. Using any suitable technique, a layer of conductive traces, such as silver, may be applied to establish the interconnections, as shown in FIGS. 2, 4 and 5. Using any suitable technique, a layer of resistive material, such as PTC ink, may be applied for heat generating elements 48 and 72-78, which may have dimensions in the range of 4 to 6 millimeters for length and 2 to 3 millimeters for width. Using any suitable technique, a layer of dielectric material, such as a dielectric ink, may be applied over the substrate and previously-applied materials, with the exception of the traces and surface mount regions. Using any suitable technique, a layer of dielectric material 84, such as dielectric ink, may be applied over trace 85 to insulate it from later-applied trace 86. Using any suitable technique, conductive trace 86, such as silver, may be applied to establish the interconnection, as shown in FIG. 5. Surface mount components 50, 52 and 58-68 may be coupled to substrate 80 using any suitable technique. An embossing process may be employed for switch 46, as shown in FIGS. 4A and 4B. In FIG. 4, the substrate portion around contact region 46C is embossed, creating a natural separation between contact region 46B and 46C, as shown in FIG. 4A. Depression of switch 46 makes contact between contact regions 46B and 46C to close the circuit and initiate battery testing. Embossing may be performed using any suitable process and at any suitable time. Voltage testers 40 may be die cut using any suitable process for their removal from the substrate sheet 80. Terminals 42 and 44 may be connected to the individual battery testers 40, after separation. A crease or fold 82 may be provided in substrate 80 to properly align and separate contact regions 46B and 46C of switch 46. Voltage tester 40 may be so fabricated into a more compact tester of approximately 2-3 square inches in area, as compared to prior voltage tester 10 covering an area of approximately 11-12 square inches.

Other embodiments of the invention will be apparent to those skilled in the art from consideration of the specification and practice of the invention disclosed herein. It is intended that the specification and examples be considered as exemplary only, with a true scope and spirit of the invention being indicated by the following claims. For example, those skilled in the art understand that the number of indicators may change, as well as the rated battery voltage. Moreover, in an alternative embodiment, reference voltage circuit 52 may comprise a surface-mounted adjustable precision shunt regulator, such as the TL431 available from Texas Instruments.

1. An apparatus for measuring voltage of a voltage source, the apparatus comprising:
a substrate;
a plurality of temperature responsive displays printed on the substrate;
a plurality of heat generating elements printed on the substrate, each heat generating element being thermally coupled to at least one of the temperature responsive displays;
a reference voltage circuit coupled to the substrate and operative to produce a reference voltage;
a voltage divider network coupled to the substrate and including a plurality of surface mounted resistors electrically connected in series and operative to produce a plurality of voltages; and
a plurality of comparator circuits embodied in a surface mounted device, each comparator circuit operative to:
receive the reference voltage and a respective voltage of the plurality of voltages produced by the voltage divider network; and
selectively allow current to flow through at least one of the heat generating elements when the respective voltage supplied by the voltage divider network exceeds the reference voltage.

2. The apparatus of claim 1 wherein each heat generating element comprises a printed resistor.

3. The apparatus of claim 1 wherein each temperature responsive display includes a thermochromic material.

4. The apparatus of claim 1 wherein the reference voltage circuit comprises a voltage regulating diode.

5. The apparatus of claim 1 wherein the reference voltage circuit comprises a zener diode.

6. The apparatus of claim 5 further including a current limiting resistor in electrical series with the zener diode.

7. The apparatus of claim 1 wherein the reference voltage circuit provides a substantially equivalent reference voltage to each comparator circuit.

8. The apparatus of claim 1 wherein the substrate comprises a material suitable to be repeatedly exposed to heat dissipation not in excess of 1.5 watts per square inch over any portion of the material without damaging the material.

9. The apparatus of claim 1 further including a switch operative to selectively complete a circuit to permit measuring the voltage of the voltage source.

10. The apparatus of claim 9 wherein the switch comprises a printed switch.

11. The apparatus of claim 10 wherein the switch comprises a first conductive region and a second conductive region, the first and second conductive regions being located on the same side of the substrate, but on different sections of the substrate, the different sections being separated by a fold in the substrate.

12. The apparatus of claim 10 wherein the switch comprises a first conductive region and a second conductive region, either of the first and second conductive regions being located on a portion of the substrate that is adapted to permit a user to tactilely detect closing and opening of the switch.

13. The apparatus of claim 12 wherein the portion of the substrate comprises a resilient embossed portion.

14. The apparatus of claim 9 further including a printed resistor on the substrate for placing a load on the voltage source when the switch is closed to improve voltage measuring accuracy.

15. The apparatus of claim 14 further including a temperature responsive display thermally coupled to the printed resistor, the temperature responsive display operative to indicate that the switch is closed, when the switch is closed and the voltage source provides sufficient current through the printed resistor.

16. The apparatus of claim 3 wherein the thermochromic material has a transition temperature greater than 45 degrees Celsius.

17. The apparatus of claim 2 wherein each printed resistor includes positive temperature coefficient ink.

18. The apparatus of claim 14 wherein the printed resistor includes positive temperature coefficient ink

19. The apparatus of claim 1 wherein each voltage of the plurality of voltages produced by the voltage divider network is a function of a ratio of resistances for the surface mounted resistors.

20. An apparatus for measuring voltage of a voltage source, the apparatus comprising:
a substrate;
a plurality of temperature responsive displays coupled to the substrate;
a plurality of heat generating elements coupled to the substrate, each heat generating element including a positive temperature coefficient ink and being thermally coupled to at least one of the temperature responsive displays;
a reference voltage circuit coupled to the substrate and operative to produce a reference voltage;
a voltage divider network coupled to the substrate and operative to produce a plurality of voltages; and
a plurality of comparator circuits coupled to the substrate, each comparator circuit operative to:
receive the reference voltage and a respective voltage of the plurality of voltages produced by the voltage divider network; and
selectively allow current to flow through at least one of the heat generating elements when the respective voltage supplied by the voltage divider network exceeds the reference voltage.

21. An apparatus for measuring voltage of a voltage source, the apparatus comprising:
a substrate;
a plurality of temperature responsive displays coupled to the substrate;
a plurality of heat generating elements coupled to the substrate, each heat generating element being thermally coupled to at least one of the temperature responsive displays;
a reference voltage circuit coupled to the substrate and operative to produce a reference voltage;
a voltage divider network coupled to the substrate and operative to produce a plurality of voltages;
a switch operative to selectively complete a circuit to permit measuring the voltage of the voltage source; and
a plurality of comparator circuits coupled to the substrate, each comparator circuit operative to:
receive the reference voltage and a respective voltage of the plurality of voltages produced by the voltage divider network; and
selectively allow current to flow through at least one of the heat generating elements when the respective voltage supplied by the voltage divider network exceeds the reference voltage.
